(19) United States
(12) Patent Application Publication
(10) Pub. No.: US 2009/0091033 A1
(43) Pub. Date: Apr. 9, 2009

(54) Fabrication of metal oxide films

(76) Inventors: Wei Gao, Auckland (NZ); Zheng-wei Li, Auckland (NZ)

Correspondence Address: BENESCH, FRIEDLANDER, COPLAN & ARONOFF LLP;ATTN: IP DEPARTMENT DOCKET CLERK, 2300 BP TOWER, 200 PUBLIC SQUARE, CLEVELAND, OH, 44114, US

(21) Appl. No.: 11/921,146

(22) PCT Filed: May 16, 2006
(86) PCT No.: PCT/NZ2006/000121

§ 371 Date: Nov. 19, 2008

(30) Foreign Application Priority Data
May 27, 2005 (AU) 2005902739

(51) Int. Cl. H01L 23/532; H01L 21/70

(52) U.S. Cl. 257/741; 438/608; 257/E21.535; 257/E23.157

(57) ABSTRACT

A process of fabricating a metal oxide film includes depositing a multiphase, metal-based precursor film comprising the metal and an oxide of the metal on a substrate. The process further includes thermally growing a metal oxide film from the precursor film in a humid atmosphere for a predetermined period of time and at a predetermined temperature.

### CROSS-REFERENCE TO RELATED APPLICATIONS

The present application claims priority from Australian Provisional Patent Application No 2005902739 filed on 27 May 2005, the contents of which are incorporated herein by reference.

### FIELD OF THE INVENTION

This invention relates to the fabrication of metal oxide films. More particularly, the invention relates to a process of fabricating a metal oxide film. While the invention has particular application in the field of fabricating zinc oxide films, one of ordinary skill in the art will appreciate that it could also be used in the fabrication of other suitable metal oxide films such as, for example, titanium oxide, aluminium oxide, yttrium oxide, zirconium oxide, magnesium oxide, silicon oxide films, or the like.

### BACKGROUND TO THE INVENTION

In the preparation of zinc oxide films, oxidation treatment of a zinc precursor film has to date been conducted in air or dry oxygen. Observations on such films formed at temperatures greater than 500° C. with exposure times exceeding approximately 1 hour found that their mechanical properties were relative poor and films so formed were prone to cracking and spallation.

Further, in order to achieve colour emissions from zinc oxide films, it has, in the past, been necessary to dope such zinc oxide films. Various types of dopants have been required to achieve the desired colour emissions. For example, in order to obtain red/orange emissions from zinc oxide films, the zinc oxide films were doped with lithium, europium, and other rare earth element ions. Polymer alloying has also been used to obtain other colour emissions from zinc oxide films. Both of these methods have involved additional steps and materials with the resultant increase in costs.

In order to obtain porous oxide films, techniques such as sol-gel, direct deposition from aqueous solutions, sputtering, ultrasonic pyrolysis and hydrothermal crystallisation methods have been used. The sol-gel technique has been regarded as the most advantageous method for the preparation. of porous crystalline thin films. However, a major drawback of this method is that it requires the use of expensive metallic-organic precursors which are also difficult to dispose of, use of polymeric additives and use of high temperature heat treatment for removal of polymer particles formed in the films. In addition, processing has to be carefully controlled to obtain good repeatability.

### SUMMARY OF THE INVENTION

According to a first aspect of the invention, there is provided a process of fabricating a metal oxide film, the process including

depositing a multiphase, metal-based precursor film comprising the metal and an oxide of the metal on a substrate; and

thermally growing a metal oxide film from the precursor film in a humid atmosphere for a predetermined period of time and at a predetermined temperature.

The process may include providing a substrate. For example, the substrate may be a slide of glass, a piece of silicon wafer, or other suitable material, such as quartz, silicon, high temperature resistant steel substrates, or the like.

Further, the process may include depositing the metal-based precursor film on to the substrate using a suitable deposition technique. The deposition technique may be a physical vapour deposition technique such as magnetron sputtering.

The process may include depositing the precursor film in a working atmosphere comprising a mixture of an inert gas and other reactive gas, for example, oxygen.

In addition, the process may include controlling the quantity of reactive gas so that it is lower than a critical level for the full formation of the metal oxide or other compounds through a reactive sputtering deposition process from a metal target. Therefore, the process may include maintaining the quantity of oxygen in the working atmosphere at less than 40% by volume and, preferably, in a range of from about 5% to 35% by volume to lead to the formation of a multiphase, metal-based precursor film.

Once the precursor film has been deposited on the substrate, the process may include thermally growing the metal oxide film from the precursor film in an atmosphere containing water vapour at a predetermined temperature. The process may include thermally growing the metal oxide film in a temperature in the range from about 350° C. to 1000° C., more particularly, about 400° C. to 650° C. and, optimally, about 600° C. for a predetermined period of time. The predetermined period of time may range from approximately 0.5 hour to 4 hours.

The process may include using a carrier gas for the transportation of the water vapour into an oxidation reaction zone. The process may include selecting the carrier gas from the group consisting of oxygen, nitrogen and inert gases, such as argon. The choice of carrier gas may govern the total oxygen content in the growth atmosphere and then the oxidation rate.

The process may include controlling the water vapour partial pressure in the oxidising gas atmosphere. More particularly, the process may include maintaining the water vapour partial pressure in a range of about 5% to 100% at atmospheric pressure.

Further, the process may include controlling at least one of a depositing and oxidising atmosphere to obtain a desired colour emission.

The process may include selecting the metal from the class of transition metals. The transition metal may be zinc or, instead, it may be titanium.

Further, the process may include modifying the metal oxide film by doping.

Still further, the process may include growing a nanorod array on a surface of the metal oxide film. The process may include controlling orientation of nanorods of the array by controlling surface of the metal oxide film. The metal oxide film may therefore act as a template for the growth of the nanorod array. The orientation of the nanorods may be controlled by controlling surface properties of the film. The template may be a partially oxidised metal.

According to a second aspect of the invention, there is provided a metal oxide film which includes a metal oxide film thermally grown in a humid atmosphere from a multiphase precursor film layer comprising the metal and an oxide of the metal.

The metal oxide film may be a highly porous metal oxide film having a particle size less than 100 nm, more particularly, about 20 nm to 80 nm.

The multiphase precursor film may be formed through a partial reactive deposition, the structure of the deposited precursor film being dependent on the quantity of reactive gas introduced during the deposition phase.

The metal oxide film may have a relative intensity ratio of green emissions to red emissions ranging from about 1.43 to 0.024 dependent on the reactive gas content during the deposition phase and on the oxygen content in the atmosphere during the growth phase.

The metal may be a transition metal. More particularly, the transition metal may be zinc. Thus, the metal oxide film formed may be a zinc oxide film. Instead, the transition metal may be titanium to form a titanium oxide film.

The metal oxide film may be modified by the inclusion of at least one dopant.

The metal oxide film may include a nanorod array on a surface thereof. Orientation of nanorods of the array may be controlled by a state of the surface.

### BRIEF DESCRIPTION OF THE DRAWINGS

Exemplary embodiments of the invention are now described with reference to the accompanying drawings in which:

FIGS. 1A and 1B show two scanning electron microscope images of metal oxide films fabricated in accordance with embodiments of the invention;

FIG. 2 shows photoluminescence spectra of a metal oxide film fabricated in accordance with an embodiment of the invention;

FIG. 3 shows a schematic representation of an initial step in the fabrication of the metal oxide film;

FIG. 4 shows a graph illustrating the effect of doping on defect related colour emission from a metal oxide film fabricated in accordance with an embodiment of the invention;

FIG. 5 shows a scanning electron microscope image of a porous metal oxide film, fabricated in accordance with an embodiment of the invention, doped with a dopant;

FIG. 6 shows a scanning electron microscope image of a porous metal oxide film, fabricated in accordance with an embodiment of the invention, doped with a different dopant;

FIG. 7 shows surface morphology and cross-sectional scanning electron microscope images of a porous metal oxide film, fabricated in accordance with an embodiment of the invention, with non-oriented metal oxide nanorods grown on the metal oxide film;

FIG. 8 shows a scanning electron microscope image of a metal oxide film, fabricated in accordance with an embodiment of the invention, of lower porosity with well-aligned zinc oxide nanorods grown on the metal oxide film;

FIG. 9 shows a scanning electron microscope image of a porous metal oxide film, fabricated in accordance with an embodiment of the invention, of a different metal and formed at a first predetermined temperature; and

FIG. 10 shows a scanning electron microscope image of a porous metal oxide film, fabricated in accordance with an embodiment of the invention, of the same metal as in FIG. 9 but formed at a second predetermined temperature.

### DETAILED DESCRIPTION OF EXEMPLARY EMBODIMENTS

In the fabrication of a metal oxide film, more particularly, a zinc oxide film, a glass substrate 10 (FIG. 3) is placed in a chamber 12 of a physical vapour deposition device which, preferably, is in the form of a magnetron sputtering device 14.

Those skilled in the art will appreciate that other suitable deposition devices or techniques could be used such as chemical vapour deposition, electron beam evaporation, molecular beam epitaxy, pulsed laser deposition, sol-gel, spray pyrolysis, methods based on vapour-liquid-solid mechanisms, or the like.

In the magnetron sputtering device 14, a target 16 is placed in the chamber 12 in spaced relationship relative to the substrate 10.

In this case, the target 16 is a high purity zinc target which is bombarded with ionised, inert gas atoms, more particularly, argon atoms 18. The magnetron causes electrons 20 to be held captive near the target 16 and the target, zinc atoms 22 released from the target 16 accumulate on the substrate 10 to form a precursor film layer 24.

In this embodiment of the invention, the magnetron sputtering occurs in the presence of a further, reactive gas. More particularly, the sputtering occurs in the presence of oxygen so that the precursor film 24 comprises a proportion of zinc metal as well as the oxide of the zinc.

The amount of oxygen introduced into the chamber 12 is lower than the critical content required for the full formation of zinc oxide films through a reactive sputtering deposition process. In particular, the quantity of oxygen is maintained at less than 40%. Thus, a multiphase precursor film 24, containing zinc and its oxide, is formed via a partial reactive deposition. The introduction of oxygen into the working atmosphere significantly changes the structure of the film deposited. Formation of a multiphase precursor film 24 containing an oxide dispersed in the metallic matrix leads to a precursor film 24 with fine particle size and a certain degree of porosity.

By controlling the deposition and oxidation process of the precursor film 24, the physical and optical properties of the zinc oxide film so formed can be modulated. Still further, controllable colour emissions from the zinc oxide film is possible.

The ratio of oxygen to the ionised argon 18 in the chamber 12 of the magnetron sputtering device 14 is selected to be in the range of about 10% to 30% and is regulated by the use of two mass flow controllers (not shown) separately.

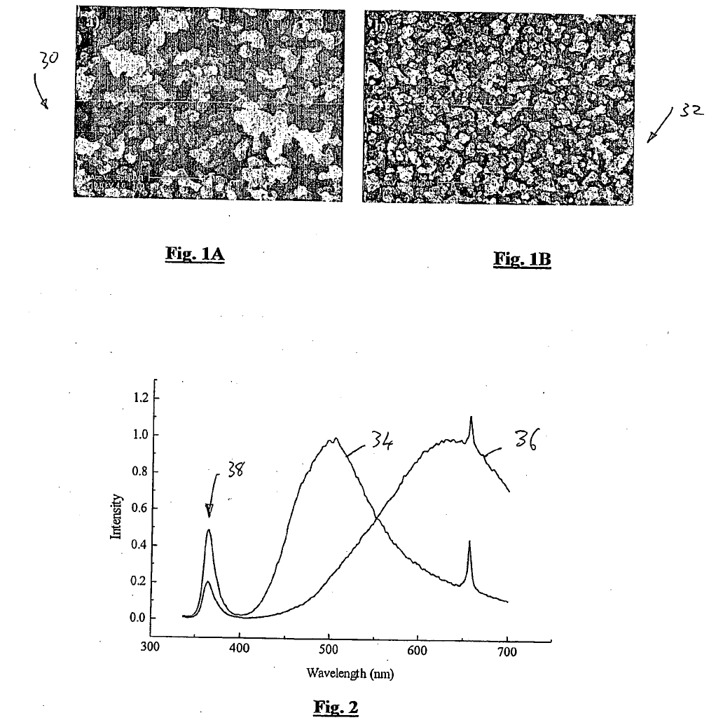

As indicated above, the presence of oxygen in the deposition phase of the precursor film 24 results in the formation of a highly porous zinc oxide film. Two examples of zinc oxide film are shown in FIGS. 1A and 1B of the drawings. In FIG. 1A, the scale of the image is 1 μm and shows a zinc oxide film 30 thermally grown from a precursor film 24 deposited in an atmosphere having an argon to oxygen ratio of 9:1. In FIG. 1B, the scale of the image also being 1 μm, a zinc oxide film 32 is shown thermally grown from a precursor film 24 deposited in an atmosphere having an argon to oxygen ratio of 8:2.

It is therefore apparent that the introduction of oxygen into the sputtering gas atmosphere significantly changes the morphology and structure of the precursor film 24. Incorporation of oxygen into the argon atmosphere leads to the partial formation of zinc oxide with the quantity of zinc oxide increasing with the increase of oxygen in the argon atmosphere.

Once the film 24 has been grown on the substrate 10, the substrate 10, carrying the film 24, is removed from the chamber 12 of the sputtering device 14 and is placed in a heating chamber (not shown) to undergo thermal oxidation. In the heating chamber, a zinc oxide film is formed by exposing the precursor film 24 to oxygen. The oxygen is entrained in an atmosphere having a high content of water vapour. More particularly, about 70% of the atmosphere comprises water vapour.

In the thermal growth phase in the preparation of the zinc oxide film, water vapour is transported into the oxidation reaction zone with a carrier gas which can be pure argon and/or oxygen and/or another reactive gas such as nitrogen. With oxygen as the carrier gas, the oxidation rate is increased since oxygen is rich in the atmosphere. When nitrogen or argon is used as the carrier gas, the oxidation rate can be slowed down, the oxidation reaction being dependent on the dissociation of water.

### EXAMPLE

An unbalanced magnetron sputtering device 14 is used for the deposition of the zinc-based precursor film 24. The target 16 used is zinc with a purity of 99.99%. The substrate 10 is a glass substrate with a typical size of 15×10 mm.

Before being loaded into the chamber 12, each substrate 10 is ultrasonically cleaned in acetone, rinsed with alcohol and distilled water and blow dried.

The chamber 12 is evacuated down to a pressure of approximately 2×10⁻⁶ Torr. Argon with a pressure of 20 mTorr is introduced into the chamber 12 to initialise a plasma with a radio frequency power of 500 W for surface cleaning.

When this process is finished, the chamber 12 is re-filled with argon or a mixture of argon and oxygen at a total pressure of 10 mTorr and a direct current power of approximately 1 Wcm² is applied to the target 16. Deposition is started by opening a target shutter (not shown) of the magnetron sputtering device 14 and occurs for 5 minutes to obtain a precursor film 24 with a typical thickness of approximately 500 nm. During deposition, the substrate 10 is rotated in front of its target at a speed of approximately 3 rpm. The substrate 10 is not separately heated so that its temperature is slightly higher than ambient temperature.

Upon completion of the growth of the precursor film 24, the substrate 10 is removed from the magnetron sputtering device 14 and is placed in a quartz tube heated in a tube furnace. The precursor film 24 is subjected to thermal oxidation treatment.

The oxidising gas used is oxygen with a water vapour content of approximately 70%. The quartz tube is maintained at a temperature of approximately 600° C. for a period of approximately 2 hours. After this time period, the substrate 10 carrying the zinc oxide film is quickly removed from the tube furnace and is cooled to ambient temperature in the presence of the same gas atmosphere being a combination of oxygen and water vapour in a ratio of approximately 3:7.

In the preparation of the zinc oxide film, the precursor film 24 was deposited in an atmosphere of pure argon, an argon to oxygen ratio of 9:1 and an argon to oxygen ratio of 8:2. The precursor film was then subjected to a thermal oxidation treatment as described above in the atmosphere of oxygen with approximately 70% water vapour.

The room temperature photoluminescence measurements show that the defect related emission could be fitted into two peaks, one green and one red/orange. The relative intensities of these peaks were highly dependent on the deposition condition. For the three atmospheres described above, the ratio of green to red was 0.70, 0.42 and 0.024 showing that, as the oxygen partial pressure in the sputtering atmosphere increased, the red emission increased significantly.

For the zinc-based precursor film 24 deposited in an atmosphere of argon with 10% oxygen, after thermal oxidation in the atmosphere of argon with 70% of water vapour, the ratio of green to red emissions increased from 0.42 to 1.43 indicating an extremely strong green emission property. This provides an indication that the oxidation atmosphere also greatly influences the optical properties of the zinc oxide film.

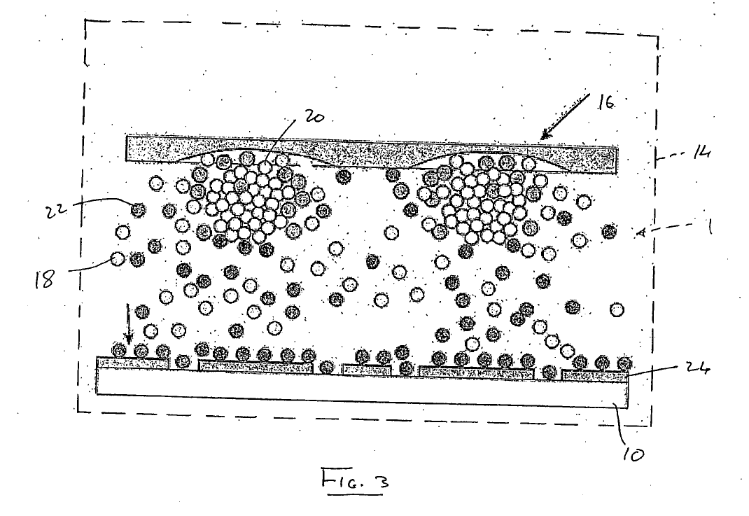

FIG. 2 shows an example of photoluminescence spectra of a zinc oxide film grown by thermal oxidation in a wet atmosphere. The curve 34 is the green spectrum emission and the curve 36 is the red spectrum emission. It will be noted that the green emission is centred in a wavelength region of approximately 518-534 nm and the red/orange emission shifted from approximately 616 nm to 647 nm monotonically as the oxygen content increased. The relative intensity ratios of green to red decrease, as indicated above, with increasing oxygen content in the sputtering atmosphere indicating that the deposition conditions strongly influence the defect related emissions and the defect centres for the two photoluminescent bands are competitive with each other. It is also to be noted that an ultraviolet emission 38 is centred at approximately 374-376 nm.

It is therefore an advantage of the invention that it is possible to control the defect chemistry and emission property of undoped zinc oxide films by controlling the structure and composition of the precursor films. This two-step deposition-oxidation technique is also a simple way for preparing highly porous zinc oxide film over large surface areas. Such highly porous films over large surface areas could find applications in the catalytic industry, for example, for use in the degradation of organic pollutants in waste water. Thus, a zinc oxide catalyst could be used in place of a more expensive titanium oxide catalyst.

Superhydrophobicity and superhydrophilicity on the surfaces of zinc oxide film nanostructures have been observed. Recently, it has also been suggested that a tunable surface wettability, i.e. the transition between superhydrophobicity and superhydrophilicity under ultraviolet light illumination could be realized on zinc oxide thin films with suitable surface geometry and structure. With this property, glass windows coated with zinc oxide films manufactured in accordance with the teaching of the present invention could exhibit self-cleaning properties as already observed on titanium dioxide films.

In addition, it has also been observed that multilayer thin films of silica nanoparticles could be created by layer-by-layer assembly with controllable levels of nano-porosity. The surface wettability of these thin films could be controlled by controlling surface nano-porosity. Since the techniques described in this specification have the advantage of porosity modulation by controlling the oxygen partial pressure in the deposition phase, surface wettability of the zinc oxide thin films formed by thermal oxidation could be controlled by controlling both surface structure (geometry) and surface porosity (particle and pore sizes).

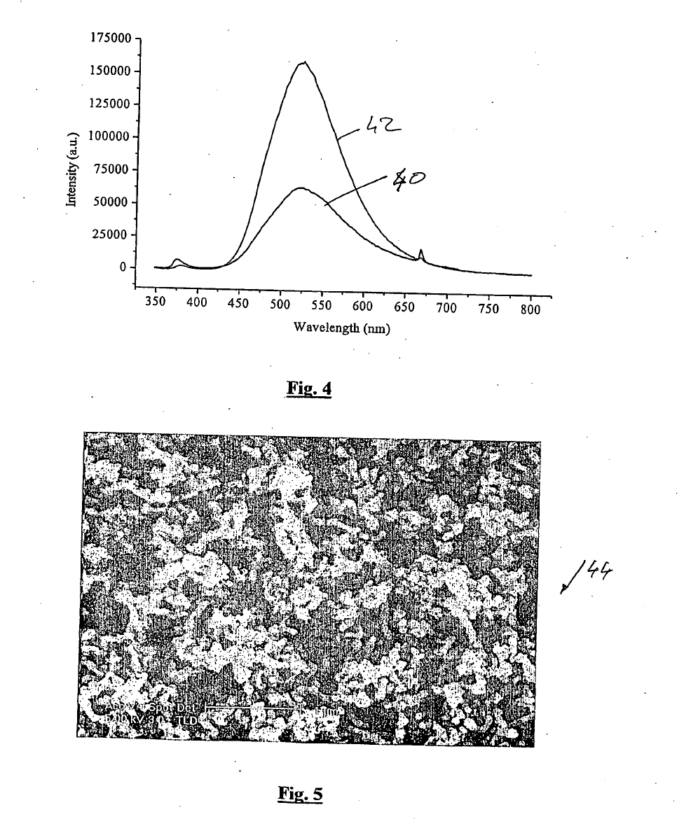

Also, as indicated above, by altering the atmosphere in which the precursor film 24 is deposited, the control of colour emission of the final zinc oxide film can be controlled. The need for dopants is therefore obviated. However, it has also been observed that doping of zinc oxide films, fabricated in accordance with the teachings of the invention, with certain elements, such as aluminium, and/or cerium, could be beneficial in respect of certain defect related colour emissions. For example, the addition of aluminium or cerium into zinc oxide could enhance the intensity of green colour emission as shown in FIG. 4 where curve 40 shows the emission spectrum of a zinc oxide film without doping and curve 42 shows the emission spectrum of the zinc oxide film doped with cerium.

Doping of either cerium or aluminium into zinc oxide films may be achieved by co-sputtering or electrochemical deposition of dopant-containing ethanol based solutions followed by thermal oxidation of these modified precursor films.

In addition, the average grain size in the zinc oxide films could be decreased, more particularly, to about 10 to 40 nm by doping. FIG. 5 of the drawings shows a scanning electron microscope image, at a scale of 1 μm, of a zinc oxide film 44 which has been doped with cerium. The cerium was doped into the film by depositing a thin cerium-containing species on to the zinc precursor film during formation of the precursor film 24. The precursor film 24 was then exposed to thermal oxidation treatment, as described above, to provide the completed zinc oxide film 44.

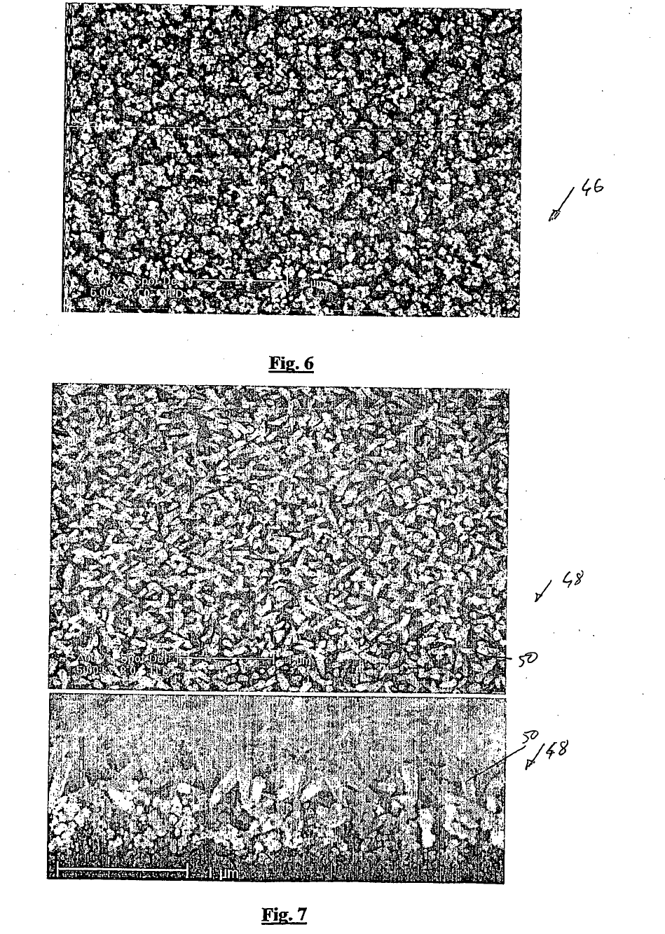

In FIG. 6 of the drawings, a zinc oxide film 46 is shown, also on a scale of 1 μm, which is doped with aluminium. Aluminium was doped into the zinc precursor film 24 by co-sputtering during formation of the precursor film 24. Thereafter, the precursor film 24 was exposed to thermal oxidation treatment, as previously described.

It is to be noted that, both in FIG. 5 and FIG. 6, the particle size of the films 44 and 46 is much smaller than that of un-doped zinc oxide films.

Still further, the use of oxygen in the deposition phase and the use of a humid atmosphere for thermal oxidation results in a highly porous zinc oxide film being formed without the need for complicated deposition-oxidation techniques or the use of expensive metallic-organic precursors. Zinc oxide films using the fabrication process of the invention can also be formed over large surface areas.

The formation of uniform and highly porous zinc oxide films on large surface areas provide for the selection of templates which can be used to prepare nanostructure materials. Zinc oxide nanorods and/or composite structures containing zinc oxide nanorods and porous films have been successfully fabricated by employing a commonly used solution growth technique. Depending on the porosity of the zinc oxide film, non-oriented and well-aligned zinc oxide nanorod arrays can be grown on these templates. The orientation of the nanorods is able to be modulated by controlling the structure, porosity and thickness of the template surface.

Referring to FIG. 7 of the drawings a plan view and a cross-sectional view of a zinc oxide film 48 is shown. The zinc oxide film 48 is a highly porous zinc oxide film on which zinc oxide nanorods 50 have been grown. Due to the fact that the underlying zinc oxide film 48 is highly porous, the nanorods 50 are non-oriented.

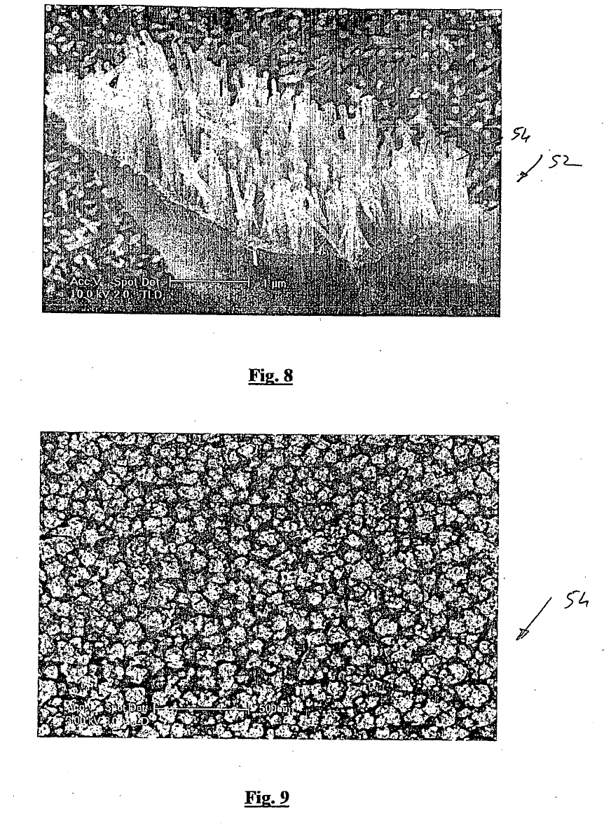

FIG. 8 shows an image of a zinc oxide film 52 which is of lower porosity than the film 48 shown in FIG. 7 of the drawings. Due to the lower porosity of the film, the nanorods 54 grown on the film 52 are more highly oriented and are well aligned. Once again, it is to be noted that the scale of the images in FIGS. 7 and 8 is 1 μm.

The structure, packing density, surface geometry and surface-related properties of the nanorod arrays are, therefore, able to be tuned. It is expected that these zinc oxide nanorod structures and/or the composite structures could find applications in catalysis, antifogging/antireflection coatings, field emission and other surface wettability related applications.

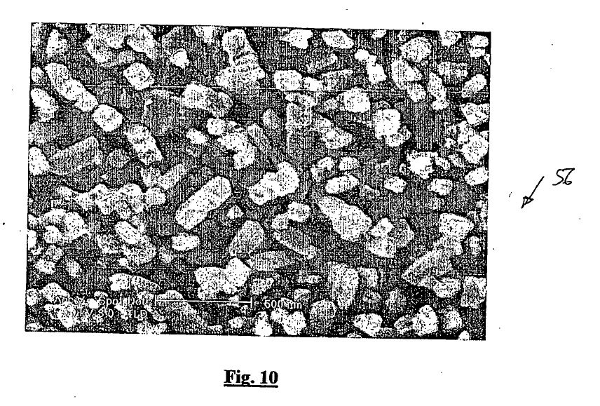

As indicated above, although the invention has been described with reference to its application in the preparation of zinc oxide films, it is also applicable in the preparation of other metal oxide films with controlled porosity or other desired structural features. FIG. 9 shows a porous titanium oxide film 56 in which the thermal oxidation phase was performed at a temperature of about 600° C. while FIG. 10 shows a porous titanium oxide film 58 in which the thermal oxidation phase was performed at a temperature of about 700° C. In contrast to the previous images, the scale of the images in FIG. 9 and 10 is 500 nm.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A process of fabricating a metal oxide film, the process including
depositing a multiphase, metal-based precursor film comprising the metal and an oxide of the metal on a substrate; and
thermally growing a metal oxide film from the precursor film in a humid atmosphere for a predetermined period of time and at a predetermined temperature.

2. The process of claim 1 which includes providing a substrate.

3. The process of claim 2 which includes depositing the metal-based precursor film on to the substrate using a deposition technique.

4. The process of claim 1 which includes depositing the precursor film in a working atmosphere comprising a mixture of an inert gas and other reactive gas.

5. The process of claim 4 which includes controlling the quantity of reactive gas so that it is lower than a critical level for the full formation of the metal oxide or other compounds through a reactive sputtering deposition process from a metal target.

6. The process of claim 5 which includes maintaining the quantity of oxygen in the working atmosphere at less than 40% by volume to lead to the formation of a multiphase, metal-based precursor film.

7. The process of claim 1 which includes, once the precursor film has been deposited on the substrate, thermally growing the metal oxide film from the precursor film in an atmosphere containing water vapour at a predetermined temperature.

8. The process of claim 7 which includes thermally growing the metal oxide film in a temperature in the range from about 350° C. to 1000° C. for a predetermined period of time.

9. The process of claim 7 which includes using a carrier gas for the transportation of the water vapour into an oxidation reaction zone.

10. The process of claim 9 which includes selecting the carrier gas from the group consisting of oxygen, nitrogen and inert gases.

11. The process of claim 7 which includes controlling the water vapour partial pressure in the oxidising gas atmosphere.

12. The process of claim 1 which includes controlling at least one of a depositing and oxidising atmosphere to obtain a desired colour emission.

13. The process of claim 1 which includes selecting the metal from the class of transition metals.

14. The process of claim 13 in which the transition metal is zinc.

15. The process of claim 1 which includes modifying the metal oxide film by doping.

16. The process of claim 1 which includes growing a nanorod array on a surface of the metal oxide film and controlling orientation of nanorods of the array by controlling surface characteristics of the metal oxide film.

17. (canceled)

18. A metal oxide film which includes a metal oxide film thermally grown in a humid atmosphere from a multiphase precursor film layer comprising the metal and an oxide of the metal.

19. The metal oxide film of claim 18 which is a porous metal oxide film.

20. The metal oxide film of claim 18 which has a particle size of less than 100 nm.

21. The metal oxide film of claim 18 in which the multiphase precursor film is formed through a partial reactive deposition, the structure of the deposited precursor film being dependent on the quantity of reactive gas introduced during the deposition phase.

22. The metal oxide film of claim 21 which has a relative intensity ratio of green emissions to red emissions ranging from about 1.43 to 0.024 dependent on the reactive gas content during the deposition phase and on the oxygen content in the atmosphere during the growth phase.

23. The metal oxide film of claim 18 in which the metal is a transition metal.

24. The metal oxide film of claim 23 in which the transition metal is zinc.

25. The metal oxide film of claim 18 which is modified by the inclusion of at least one dopant.

26. The metal oxide film of claim 15 which includes a nanorod array on a surface thereof, orientation of nanorods of the array being controlled by a state of the surface.

27. (canceled)
